(19) United States
(12) Patent Application Publication
(10) Pub. No.: US 2025/0081367 A1
(43) Pub. Date: Mar. 6, 2025

(54) FLEXIBLE DISPLAY DEVICE AND METHOD OF MANUFACTURING DISPLAY DEVICE

(71) Applicant: SAMSUNG DISPLAY CO., LTD., YONGIN-SI (KR)

(72) Inventor: TAEAN SEO, Yongin-si (KR)

(21) Appl. No.: 18/679,591

(22) Filed: May 31, 2024

(30) Foreign Application Priority Data
Aug. 30, 2023 (KR) 10-2023-0114963
Oct. 17, 2023 (KR) 10-2023-0138979

(51) Int. Cl. H05K 5/02; B32B 3/30; B32B 5/12; B32B 7/02

(52) U.S. Cl. CPC H05K 5/0217; B32B 3/30; B32B 5/12; B32B 7/02; B32B 2262/106; B32B 2305/10; B32B 2313/04; B32B 2457/20

(57) ABSTRACT

A display device includes a display panel having a fixed area and an expanded area extending from the fixed area in a first direction. A first support plate includes a first flat part disposed under the fixed area and a flexible part disposed under the expanded area. A second support plate includes a plurality of support bars arranged under the flexible part, arranged in the first direction, and extending in a second direction intersecting the first direction. The flexible part incudes a first carbon fiber. The support bars include a second carbon fiber. A size of a radius of the first carbon fiber and a size of a radius of the second carbon fiber are different from each other.

### CROSS-REFERENCE TO RELATED APPLICATIONS

This application claims priority under 35 U.S.C. § 119 to Korean Patent Application No. 10-2023-0114963, filed on Aug. 30, 2023 in the Korean Intellectual Property Office, and Korean Patent Application No. 10-2023-0138979, filed on Oct. 17, 2023 in the Korean Intellectual Property Office, the disclosures of which are incorporated by reference herein in their entireties.

### TECHNICAL FIELD

the present disclosure described herein relate to a display device and, more specifically, to a flexible display device and a method of manufacturing a flexible display device.

### DISCUSSION OF THE RELATED ART

In general, electronic devices such as smart phones, digital cameras, laptop computers, navigation devices, and smart televisions that provide images to users include display devices for displaying the images. These display devices generate images and provide the generated images to users through display screens.

In recent years, with the technological development of display devices, various types of display devices have been developed. For example, flexible display devices that may be expanded outward by being slid or unwound have been developed. The flexible display devices, of which a shape may be variously deformed, may be more easily carried and increase user convenience.

These display devices may include a display panel, a support plate disposed under the display panel, and support bars.

### SUMMARY

A display device includes a display panel including a fixed area and an expanded area extending from the fixed area in a first direction. A first support plate includes a first flat part disposed under the fixed area and a flexible part disposed under the expanded area. A second support plate includes a plurality of support bars arranged under the flexible part, arranged in the first direction, and extending in a second direction intersecting the first direction. The flexible part includes a first carbon fiber, each of the support bars include a second carbon fiber, and a size of a radius of the first carbon fiber and a size of a radius of the second carbon fiber are different from each other.

A method of manufacturing a display device includes forming a preliminary first support plate by laminating a plurality of first carbon fibers. A preliminary second support plate is formed by laminating a plurality of second carbon fibers. The preliminary first support plate is adhered to an upper surface of the preliminary second support plate. A plurality of support bars are formed by etching the preliminary second support plate. A flexible part is formed by defining a plurality of flexible openings in the preliminary first support plate. The flexible part and the support bars are connected to a display panel. A size of a radius of the first carbon fibers is smaller than a size of a radius of the second carbon fibers.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment of the present disclosure.

FIG. 2 is a perspective view illustrating a folded state of the display device illustrated in FIG. 1.

FIG. 3 is a perspective view illustrating an expansion mode of the display device illustrated in FIG. 1.

FIG. 4 is an exploded perspective view of the display device illustrated in FIGS. 1 to 3.

FIGS. 5A and 5B are cross-sectional views illustrating a contraction mode and an expansion mode of a module set illustrated in FIG. 4.

FIG. 6 is an exploded perspective view of the module set illustrated in FIG. 4.

FIG. 7 is a cross-sectional view illustrating a display module illustrated in FIG. 6.

FIG. 8 is a cross-sectional view illustrating a display panel illustrated in FIG. 7.

FIG. 9 is a plan view of the display panel illustrated in FIG. 8.

FIG. 10 is an enlarged perspective view of a first area AA1 illustrated in FIG. 6.

FIG. 11 is an enlarged plan view of a second area AA2 illustrated in FIG. 10.

FIG. 12 is a perspective view of a third area AA3 illustrated in FIG. 10.

FIG. 13 is a perspective view of a second support plate illustrated in FIG. 4.

FIG. 14 is a perspective view of a fourth area AA4 illustrated in FIG. 13.

FIG. 15 is a cross-sectional view illustrating coupling between a flexible part of FIG. 12 and support bars of FIG. 13.

FIG. 16A is a perspective view illustrating a second flat part illustrated in FIG. 13.

FIG. 16B is a perspective view illustrating the second flat part according to an embodiment.

FIG. 17A is a perspective view and 17B is a cross-sectional view illustrating a second support plate according to an embodiment.

FIGS. 18A to 18E are perspective views illustrating a method of manufacturing the flexible part and the support bars.

### DETAILED DESCRIPTION

In the present specification, the expression that a first component (or an area, a layer, a part, a portion, etc.) is “disposed on”, “connected with” or “coupled to” a second component may mean that the first component is directly disposed on/connected with/coupled to the second component or may mean that a third component is interposed therebetween.

The same reference numerals may refer to the same components throughout the specification and the drawings. Further, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

The term “and/or” includes all combinations of one or more components that may be defined by associated configurations.

The terms “first”, “second”, etc. are used to describe various components, but the components should not necessarily be limited by the terms. The terms are used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Further, the terms “under”, “beneath”, “on”, “above”, etc. are used to describe a relationship between components illustrated in the drawings. The terms have relative concepts and are described with reference to a direction indicated in the drawing.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Hereinafter, an embodiment of the present disclosure will be described in detail with reference to the drawings.

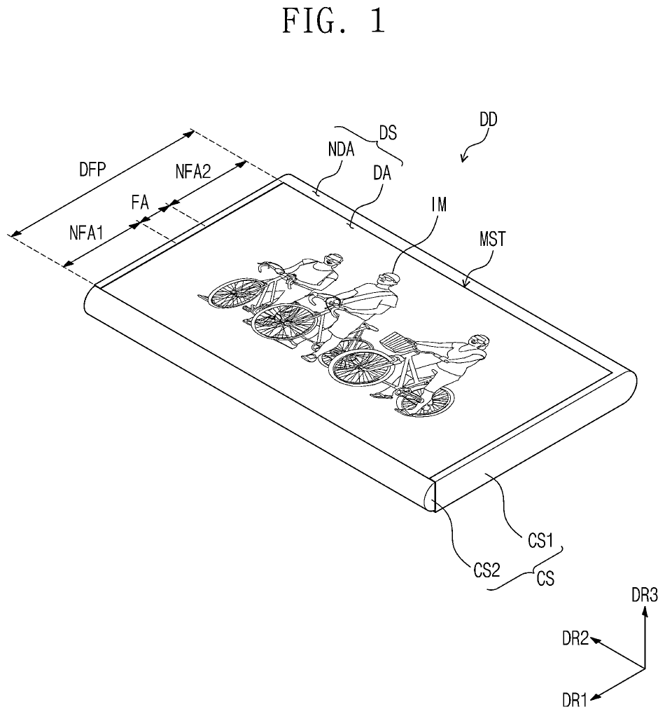

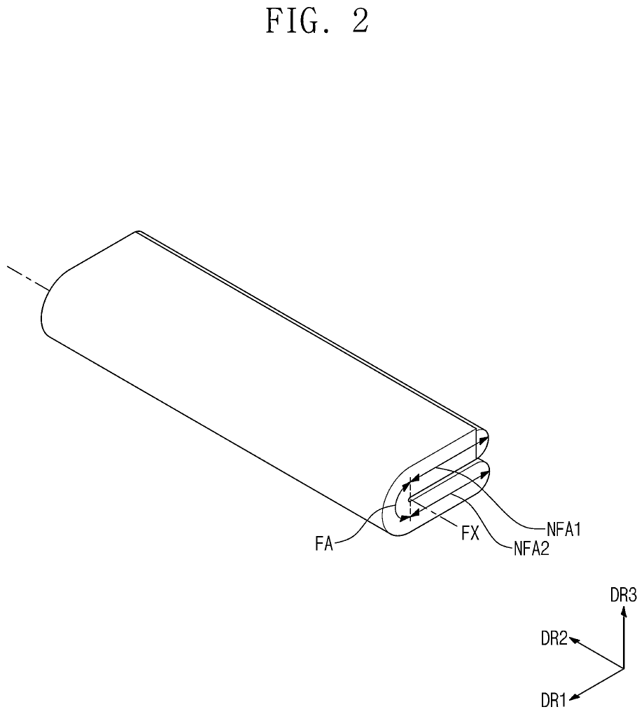

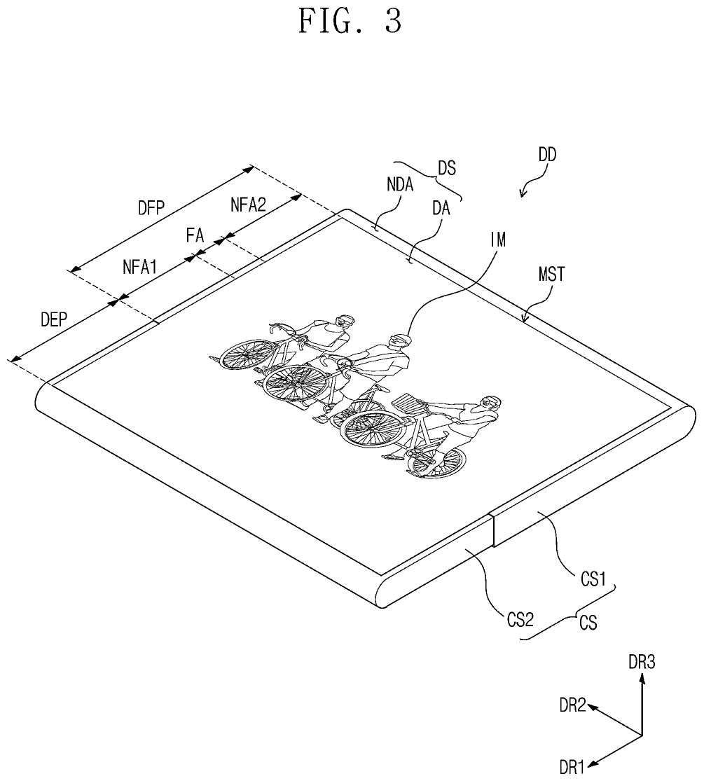

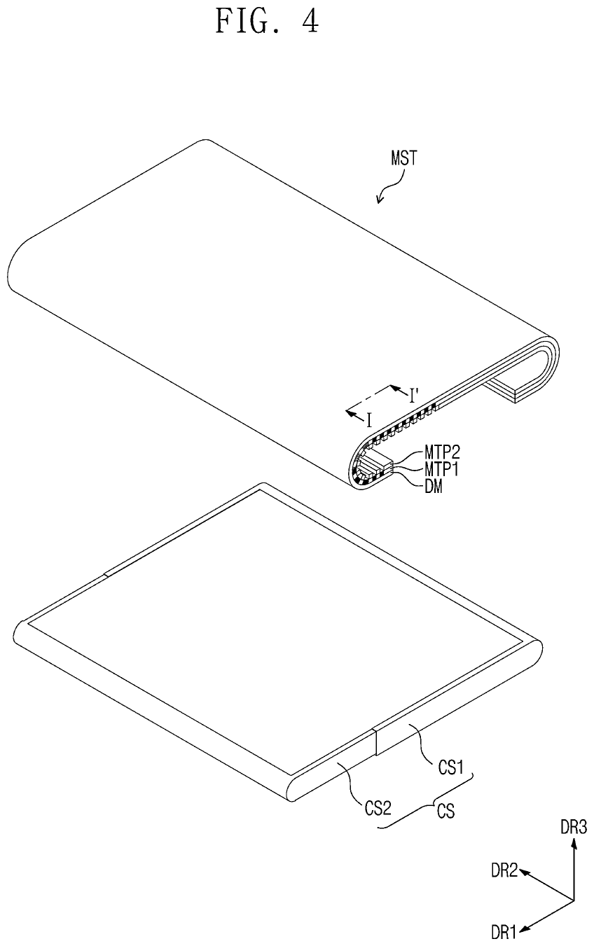

FIG. 1 is a perspective view of a display device according to an embodiment of the present disclosure. FIG. 2 is a view illustrating a folded state of the display device illustrated in FIG. 1. FIG. 3 illustrates an expansion mode of the display device illustrated in FIG. 1. FIG. 4 is an exploded perspective view of the display device illustrated in FIGS. 1 to 3.

Referring to FIGS. 1 and 2, a display device DD may have a rectangular shape having a pair of short sides extending in a first direction DR1 and a pair of long sides extending in a second direction DR2 intersecting the first direction DR1. However, the present disclosure is not necessarily limited thereto, and the display device DD may have various shapes such as a circular shape and polygonal shapes. The display device DD may be a flexible display device. Hereinafter, a direction intersecting the first direction DR1 is defined as the second direction DR2. A direction that substantially perpendicularly intersects a plane defined by the first and second directions DR1 and DR3 is defined as a third direction DR3. In the specification, the wording “when viewed on a plane” or “in a plan view” (which may be used interchangeably herein) may mean a state viewed from the third direction DR3.

The display device DD may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The first non-folding area NFA1, the folding area FA, and the second non-folding area NFA2 may be arranged in the first direction DR1.

For example, the one folding area FA and the two non-folding areas NFA1 and NFA2 are illustrated, but the numbers of the folding area FA and the non-folding areas NFA1 and NFA2 are not necessarily limited thereto. For example, the display device DD may include a plurality of non-folding areas of which the number is greater than two and a plurality of folding areas arranged between the non-folding areas.

An upper surface of the display device DD may be defined as a display surface DS, and the display surface DS may have the plane defined by the first direction DR1 and the second direction DR2. Images IM generated by the display device DD may be provided to a user through the display surface DS.

The display surface DS may include a display area DA and a non-display area NDA proximate to and at least partially surrounding the display area DA. The display area DA displays an image, and the non-display area NDA does not display the image. The non-display area NDA may surround the display area DA on multiple sides thereof and define an edge of the display device DD, which is printed in a predetermined color.

Referring to FIG. 2, the display device DD may be a display device that is in a folded or unfolded state. For example, the folding area FA may be bent about a folding axis FX parallel to the second direction DR2, and thus the display device DD may be folded. The folding axis FX may be defined as a long axis parallel to the long sides of the display device DD.

When the display device DD is folded, the first non-folding area NFA1 and the second non-folding area NFA2 may face each other, and the display device DD may be in-folded so that the display surface DS is not exposed to the outside and is therefore protected. However, an embodiment of the present disclosure is not necessarily limited thereto.

Referring to FIGS. 1, 3, and 4, the display device DD may include a module set MST and a case CS. The case CS may accommodate the module set MST. Both sides of the case CS, which are opposite to each other in the first direction DR1, may have a curved shape.

The case CS may include a first case CS1 and a second case CS2. The second case CS2 may move in a direction away from or closer to the first case CS1 in the first direction DR1.

The module set MST may be accommodated in the case CS to display the image IM. One side of both sides of the module set MST, which are opposite to each other in the first direction DR1, may be accommodated in the first case CS1. The other side of the module set MST may be accommodated in the second case CS2. Accordingly, when the second case CS2 moves from the first case CS1 in the first direction DR1, the module set MST may also move in the first direction DR1. When the second case CS2 moves in the first direction DR1, an area of an exposed surface of the module set MST may be adjusted according to the movement of the second case CS2. A contraction mode and the expansion mode of the display device DD may be implemented according to the movement of the second case CS2.

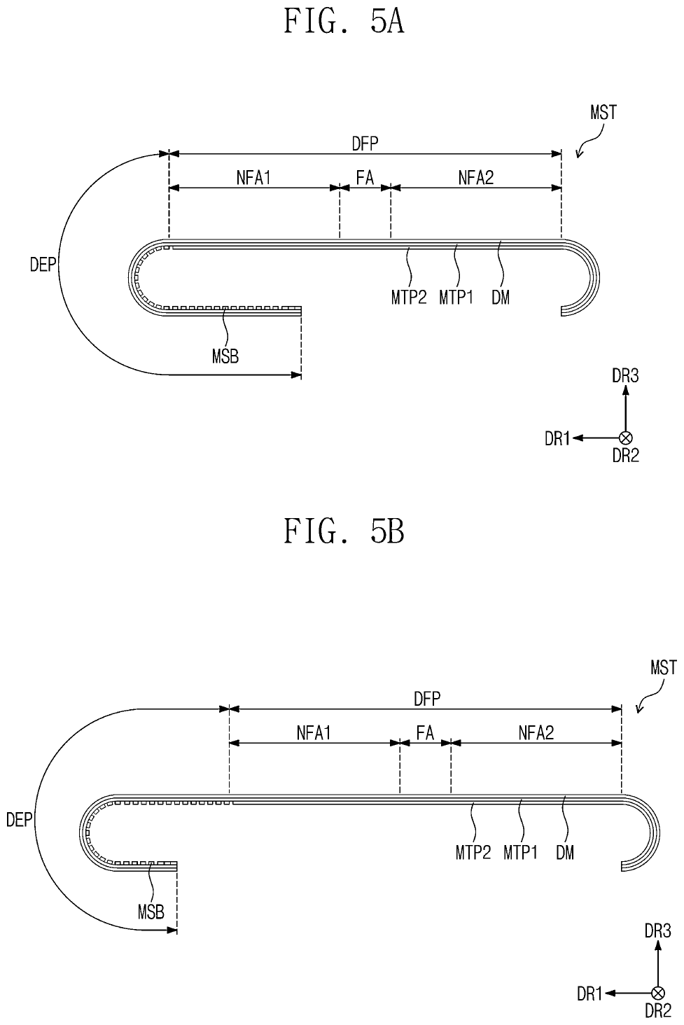

FIGS. 5A and 5B are cross-sectional views illustrating a contraction mode and an expansion mode of a module set illustrated in FIG. 4.

Referring to FIGS. 3, 4, 5A, and 5B, the module set MST may include a display module DM, a first support plate MTP1, and a second support plate MTP2. The display module DM may be a flexible display module. The display module DM may include a fixed area DFP and an expanded area DEP. When the display device DD is in the contraction mode, a portion of the display module DM, which is flatly exposed to the outside, may be defined as the fixed area DFP, and a portion of the display module DM, which is not flatly exposed to the outside, may be defined as the expanded area DEP.

When the display module DM is in the contraction mode or the expansion mode, a portion of the expanded area DEP may be flatly exposed to the outside. The expanded area DEP may extend from the fixed area DFP in the first direction DR1. As illustrated in FIG. 5B, in the expansion mode, the fixed area DFP and the expanded area DEP may be arranged in the first direction DR1. When the display device DD is in the contraction mode, as illustrated in FIG. 5A, the expanded area DEP may be disposed below the fixed area DFP.

The fixed area DFP may include the first non-folding area NFA1, the folding area FA, and the second non-folding area NFA2 that are arranged in the first direction DR1. The first non-folding area NFA1, the folding area FA, and the second non-folding area NFA2 may be substantially similar to corresponding elements described above and to the extent that an element is not described in detail with respect to this figure, it may be understood that the element is at least similar to a corresponding element that has been described elsewhere within the present disclosure.

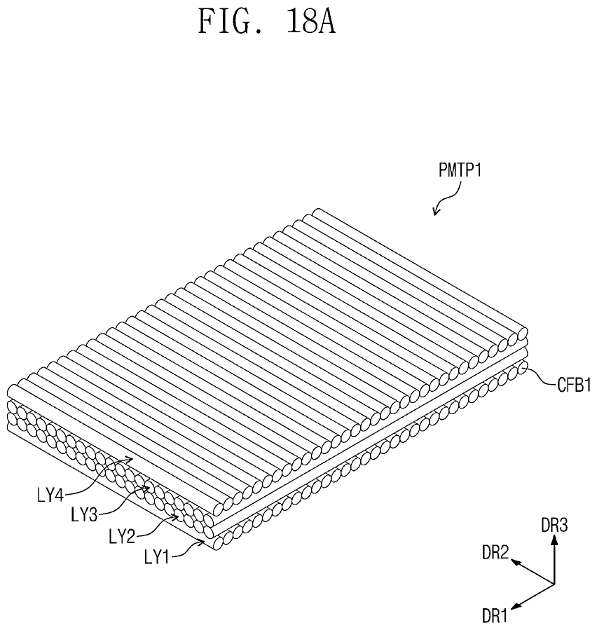

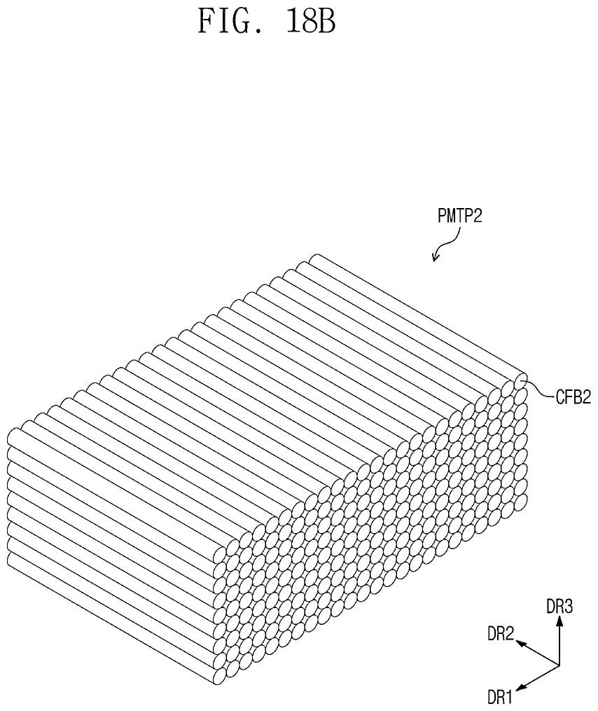

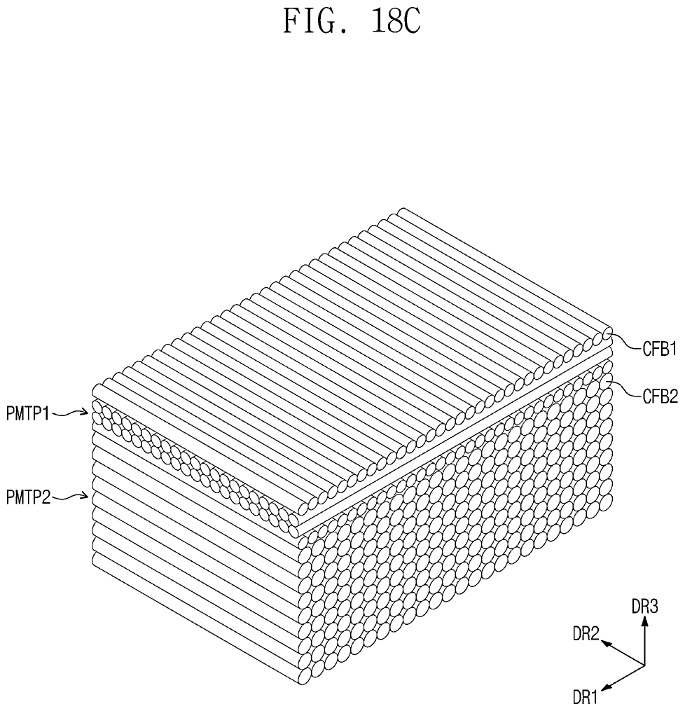

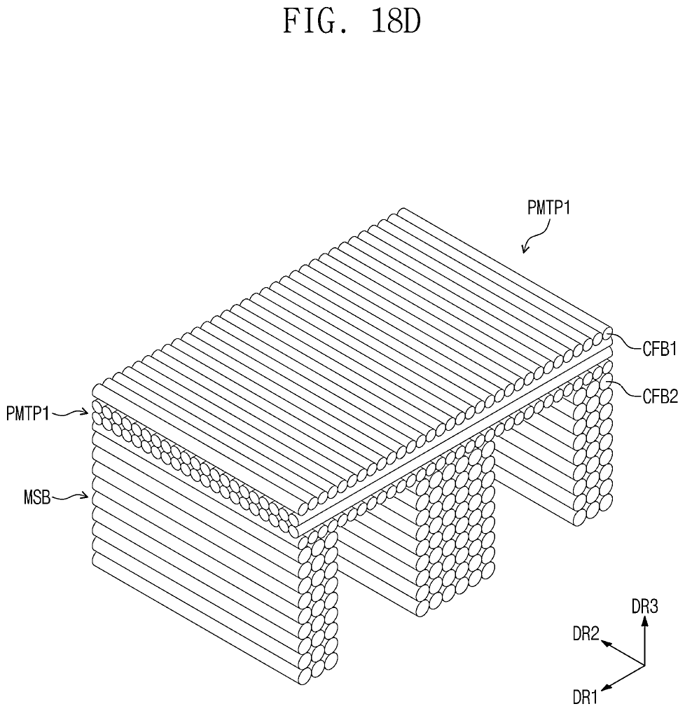

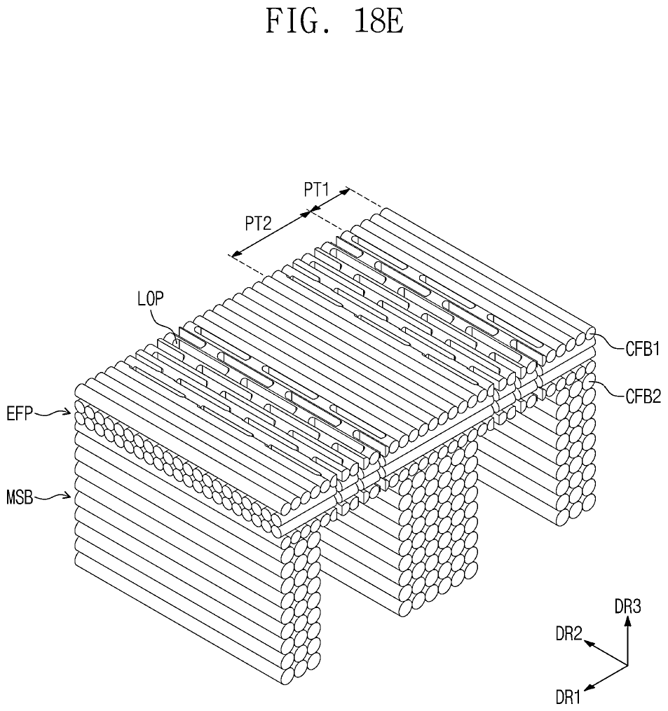

The display module DM may be supported by the first support plate MTP1 and the second support plate MTP2 that are arranged below the display module DM. The first support plate MTP1 may be disposed between the display module DM and the second support plate MTP2. The second support plate MTP2 may be disposed under the first support plate MTP1 and bonded thereto. A bonding relationship between the first support plate MTP1 and the second support plate MTP2 will be described in detail in FIGS. 18A to 18E.

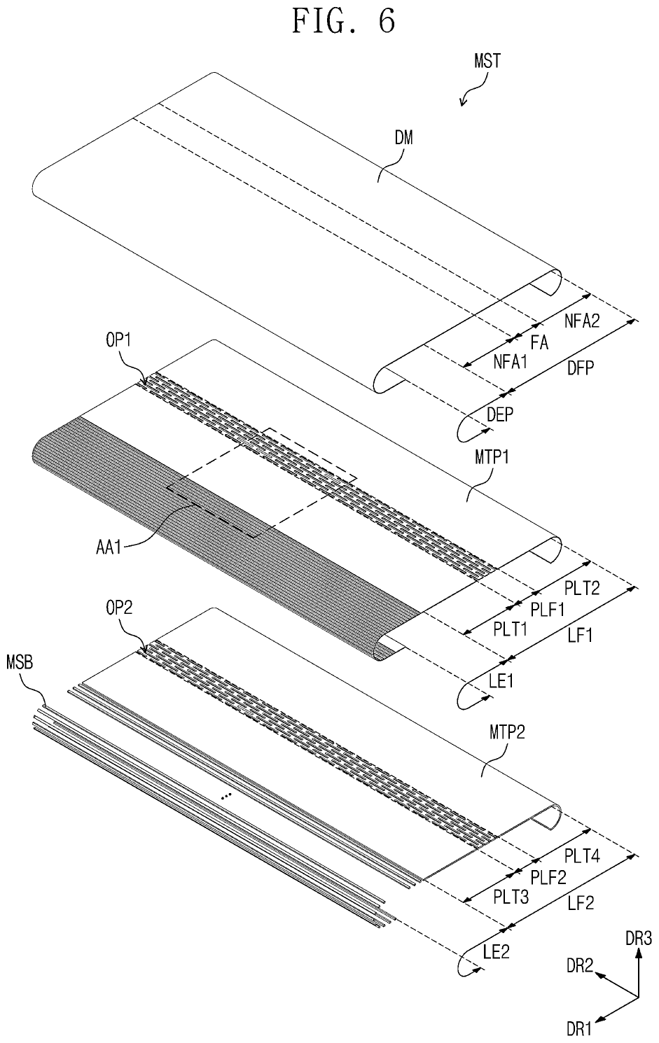

FIG. 6 is an exploded perspective view of the module set illustrated in FIG. 4.

For example, FIG. 6 is a view illustrating the module set MST when the display device DD (see FIG. 3) is in the expansion mode.

Referring to FIG. 6, both sides of the display module DM, which are opposite to each other in the first direction DR1, may have a curved shape. When the display module DM is unfolded, the display module DM may have a rectangular shape having a pair of short sides extending in the first direction DR1 and a pair of long sides extending in the second direction DR2.

The first support plate MTP1 may be disposed under the display module DM. An upper surface of the first support plate MTP1 may be attached to a lower surface of the display module DM.

The first support plate MTP1 may include a first fixed part LF1 and a first expanded part LE1. The first fixed part LF1 may overlap the fixed area DFP of the display module DM. The first expanded part LE1 may overlap the expanded area DEP. The first expanded part LE1 may extend from the first fixed part LF1.

The first fixed part LF1 may include a first plane PLT1, a first folding portion PLF1, and a second plane PLT2. The first plane PLT1, the first folding portion PLF1, and the second plane PLT2 may be arranged in the first direction DR1. The first folding portion PLF1 may extend from the first plane PLT1 in the first direction DR1. The second plane PLT2 may extend from the first folding portion PLF1. The first plane PLT1, the first folding portion PLF1, and the second plane PLT2 may be formed integrally, for example, they may together be part of a singular uninterrupted structure. The first folding portion PLF1 may be disposed between the first plane PLT1 and the second plane PLT2.

The first plane PLT1 may overlap the first non-folding area NFA1. The first folding portion PLF1 may overlap the folding area FA. The second plane PLT2 may overlap the second non-folding area NFA2.

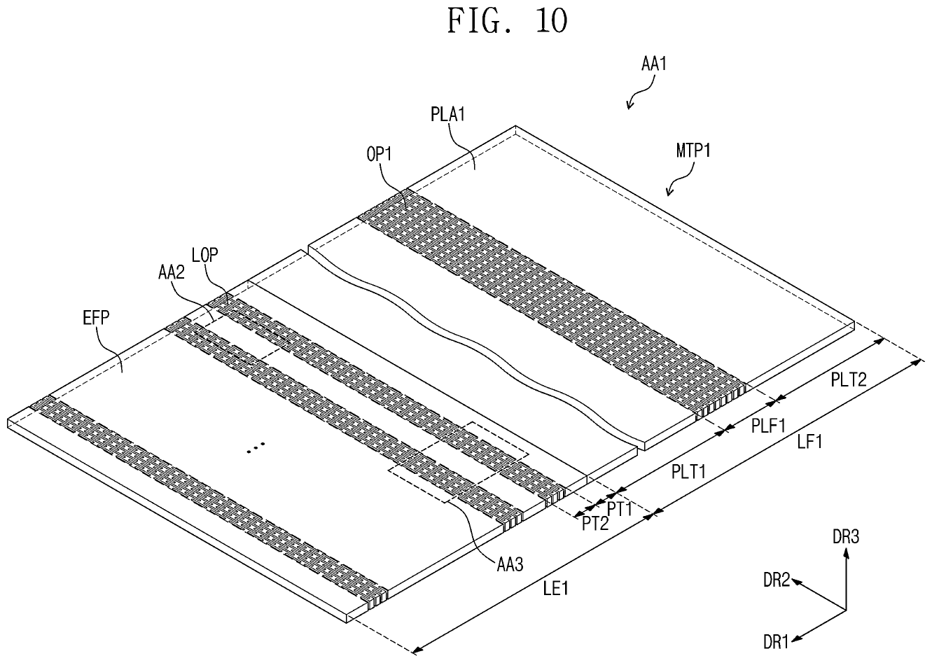

A plurality of first openings OP1 may be defined in the first folding portion PLF1. The first openings OP1 will be described in detail in FIG. 10.

The second support plate MTP2 may include a second fixed part LF2 and a second expanded part LE2. The second fixed part LF2 may overlap the first fixed part LF1 and the fixed area DFP. The second expanded part LE2 may overlap the first expanded part LE1 and the expanded area DEP. The second expanded part LE2 may include a plurality of support bars MSB.

The second fixed part LF2 may include a third plane PLT3, a second folding portion PLF2, and a fourth plane PLT4. The third plane PLT3, the second folding portion PLF2, and the fourth plane PLT4 may be arranged in the first direction DR1. The second folding portion PLF2 may extend from the third plane PLT3 in the first direction DR1. The fourth plane PLT4 may extend from the second folding portion PLF2. The second folding portion PLF2 may be disposed between the third plane PLT3 and the fourth plane PLT4. The third plane PLT3, the second folding portion PLF2, and the fourth plane PLT4 may be formed integrally, for example, they may together be part of a singular uninterrupted structure.

The third plane PLT3 may overlap the first plane PLT1 and the first non-folding area NFA1. The second folding portion PLF2 may overlap the first folding portion PLF1 and the folding area FA. The fourth plane PLT4 may overlap the second non-folding area NFA2 and the second plane PLT2.

The third plane PLT3, the second folding portion PLF2, and the fourth plane PLT4 may be planes defined by the first direction DR1 and the second direction DR2. A plurality of second openings OP2 may be defined in the second folding portion PLF2. The second openings OP2 will be described in detail in FIG. 13.

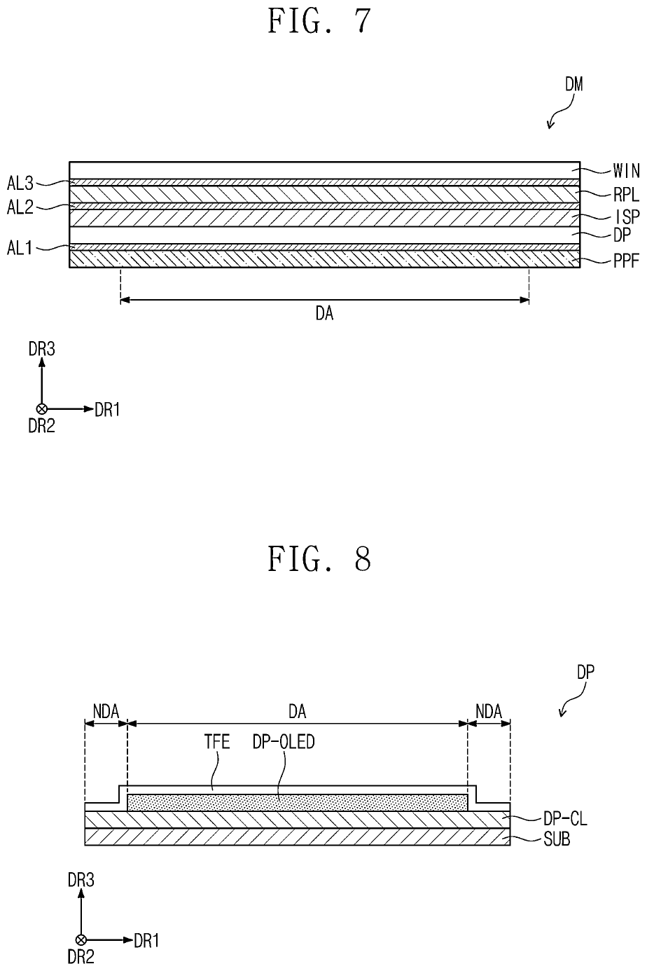

FIG. 7 is a cross-sectional view exemplarily illustrating a display module illustrated in FIG. 6.

Referring to FIG. 7, the display module DM may include a display panel DP, an input sensing unit ISP, a reflection preventing layer RPL, a window WIN, a panel protecting film PPF, and first to third adhesive layers AL1 to AL3.

The display panel DP may be a flexible display panel. The display panel DP, according to an embodiment of the present disclosure, may be a light emitting display panel, but the present disclosure is not necessarily particularly limited thereto. For example, the display panel DP may be an organic light emitting display (OLED) panel or an inorganic light emitting display panel. A light emitting layer of the organic light emitting display panel may include an organic light emitting material. A light emitting layer of the inorganic light emitting display panel may include a quantum dot and a quantum rod. Hereinafter, the display panel DP will be described as the organic light emitting display panel.

The input sensing unit ISP may be disposed on the display panel DP. The input sensing unit ISP may include a plurality of sensing units for sensing an external input in a capacitive manner. The input sensing unit ISP may be directly manufactured on the display panel DP when the display device DD is manufactured. However, the present disclosure is not necessarily limited thereto, and the input sensing unit ISP may be manufacture as a separate panel from the display panel DP and then attached to the display panel DP by an adhesive layer.

The reflection preventing layer RPL may be disposed on the input sensing unit ISP. The reflection preventing layer RPL may be defined as an external light reflection prevention film. The reflection preventing layer RPL may reduce a reflectance of an external light input from an upper side of the display device DD (see FIG. 1) toward the display panel DP.

When an external light moving toward the display panel DP is reflected by the display panel DP and provided back to a user (i.e., viewer), the display may have a mirror-like effect that is visually recognize by the user. To prevent this phenomenon, for example, the reflection preventing layer RPL may include a plurality of color filters that display the same colors as those of the pixels of the display panel DP.

The color filters may filter the external light into the same color as that of the pixels. In this case, the external light might not be visually recognized by the user. However, the present disclosure is not necessarily limited thereto, and the reflection preventing layer RPL may include a phase retarder and/or a polarizer to reduce the reflectance of the external light.

The window WIN may be disposed on the reflection preventing layer RPL. The window WIN may protect the display panel DP, the input sensing unit ISP, and the reflection preventing layer RPL from external scratches and impacts.

The panel protecting film PPF may be disposed under the display panel DP. The panel protecting film PPF may protect a lower portion of the display panel DP. The panel protecting film PPF may include a flexible plastic material such as polyethyleneterephthalate (PET).

The first adhesive layer AL1 may be disposed between the display panel DP and the panel protecting film PPF, and the display panel DP and the panel protecting film PPF may adhere to each other by the first adhesive layer AL1. The second adhesive layer AL2 may be disposed between the reflection preventing layer RPL and the input sensing unit ISP, and the reflection preventing layer RPL and the input sensing unit ISP may adhere to each other by the second adhesive layer AL2. The third adhesive layer AL3 may be disposed between the window WIN and the reflection preventing layer RPL, and the window WIN and the reflection preventing layer RPL may adhere to each other by the third adhesive layer AL3.

FIG. 8 is a cross-sectional view illustrating a display panel illustrated in FIG. 7.

For example, FIG. 8 is a cross-sectional view of the display panel DP when viewed from the second direction DR2.

Referring to FIG. 8, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include the display area DA and the non-display area NDA proximate to and at least partially surrounding the display area DA. The substrate SUB may include a flexible plastic material such as polyimide (PI). The display element layer DP-OLED may be disposed on the display area DA.

A plurality of pixels may be arranged in the circuit element layer DP-CL and the display element layer DP-OLED. Each of the pixels may include transistors arranged on the circuit element layer DP-CL and a light emitting element disposed on the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and foreign substances.

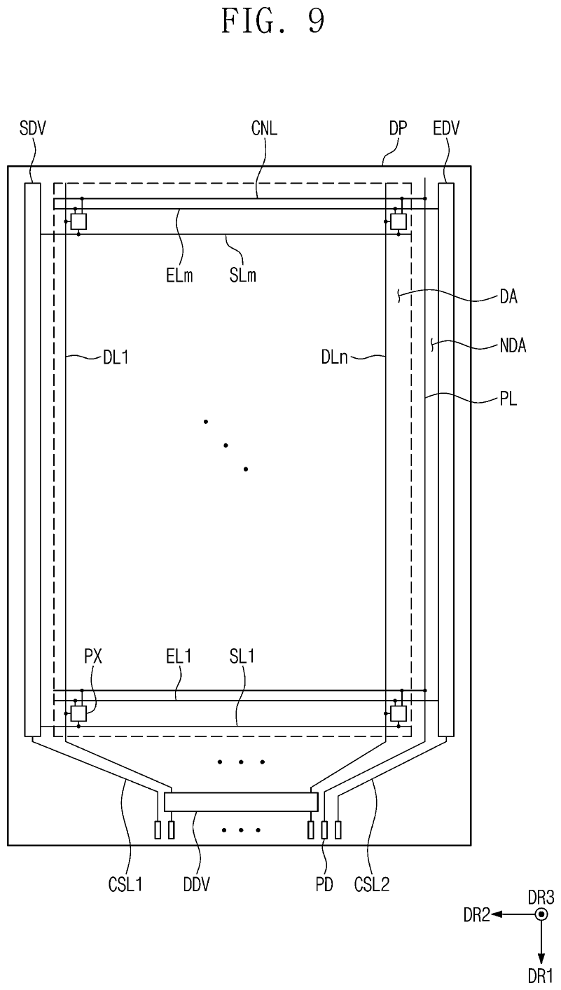

FIG. 9 is a plan view of the display panel illustrated in FIG. 8.

Referring to FIG. 9, the display panel DP may include a scan driver SDV, a data driver DDV, a light emission driver EDV, and a plurality of pads PD.

The display panel DP may have a rectangular shape having a pair of long sides extending in the first direction DR1 and a pair of short sides extending in the second direction DR2, but the shape of the display panel DP is not necessarily limited thereto. The display panel DP may include the display area DA and the non-display area NDA proximate to and at least partially surrounding the display area DA.

The display panel DP may include a plurality of pixels PX, a plurality of scan lines SL1 to SLm, a plurality of data lines DL1 to DLn, a plurality of light emitting lines ELI to ELm, first and second control lines CSL1 and CSL2, a power line PL, a plurality of connection lines CNL, and the plurality of pads PD. Here, “m” and “n” are positive integers.

The pixels PX may be arranged in the display area DA. The scan driver SDV and the light emission driver EDV may be arranged in the non-display area NDA that is adjacent to the long sides of the display panel DP. The data driver DDV may be disposed in the non-display area NDA that is adjacent to one of the short sides of the display panel DP. When viewed on a plane, the data driver DDV may be adjacent to a lower end of the display panel DP.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The light emitting lines ELI to ELm may extend in the second direction DR2 and may be connected to the pixels PX and the light emission driver EDV.

The power line PL may extend in the first direction DR1 and may be disposed in the non-display area NDA. The power line PL may be disposed between the display area DA and the light emission driver EDV, but the present disclosure is not necessarily limited thereto, and the power line PL may be also disposed between the display area DA and the scan driver SDV.

The connection lines CNL may extend in the second direction DR2, may be arranged in the first direction DR1, and may be connected to the power line PL and the pixels PX. A driving voltage may be applied to the pixels PX through the power line PL and the connection lines CNL connected to each other.

The first control line CSL1 may be connected to the scan driver SDV and extend toward the lower end of the display panel DP. The second control line CSL2 may be connected to the light emission driver EDV and extend toward the lower end of the display panel DP. The data driver DDV may be disposed between the first control line CSL1 and the second control line CSL2.

The data lines DL1 to DLn may be connected to the corresponding pads PD through the data driver DDV. For example, the data lines DL1 to DLn may be connected to the data driver DDV, and the data driver DDV may be connected to the pads PD respectively corresponding to the data lines DL1 to DLn.

The data lines DL1 to DLn may be connected to the data driver DDV, and the data driver DDV may be connected to the pads PD corresponding to the data lines DL1 to DLn.

A printed circuit board may be connected to the pads PD, and a timing controller and a voltage generator may be arranged on the printed circuit board. The timing controller may be manufactured as an integrated circuit chip and mounted on the printed circuit board. The timing controller and the voltage generator may be connected to the pads PD through the printed circuit board.

A scan control signal may be provided to the scan driver SDV through the first control line CSL1. A light emitting control signal may be provided to the light emission driver EDV through the second control line CSL2. A data control signal may be provided to the data driver DDV. The timing controller may receive image signals from an external unit, convert data formats of the image signals to satisfy interface specifications with the data driver DDV, and provide the converted image signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The light emission driver EDV may generate a plurality of light emitting signals in response to the light emitting control signal. The light emitting signals may be applied to the pixels PX through the light emitting lines ELI to ELm.

The pixels PX may receive the data voltages in response to the scan signals. The pixels PX may display an image by emitting lights having luminances corresponding to the data voltages in response to the light emitting signals. Light emitting times of the pixels PX may be controlled by the light emitting signals.

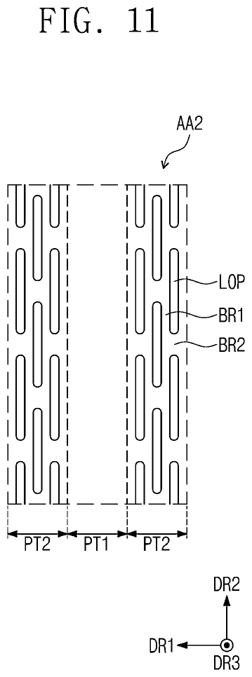

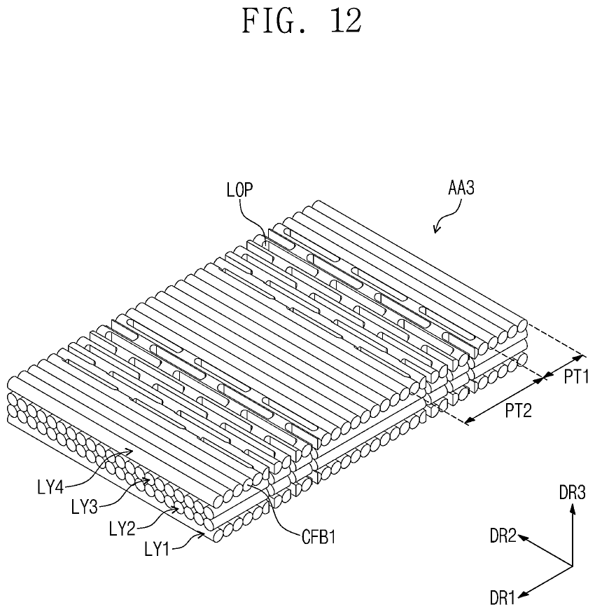

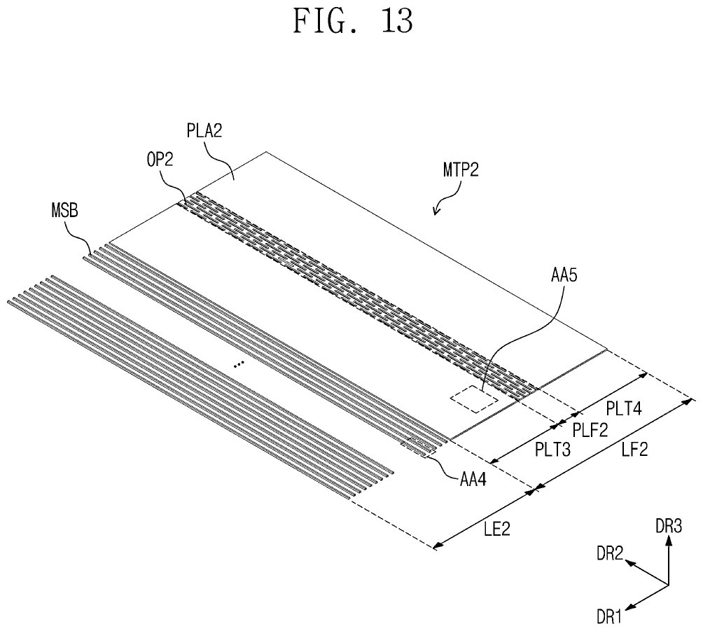

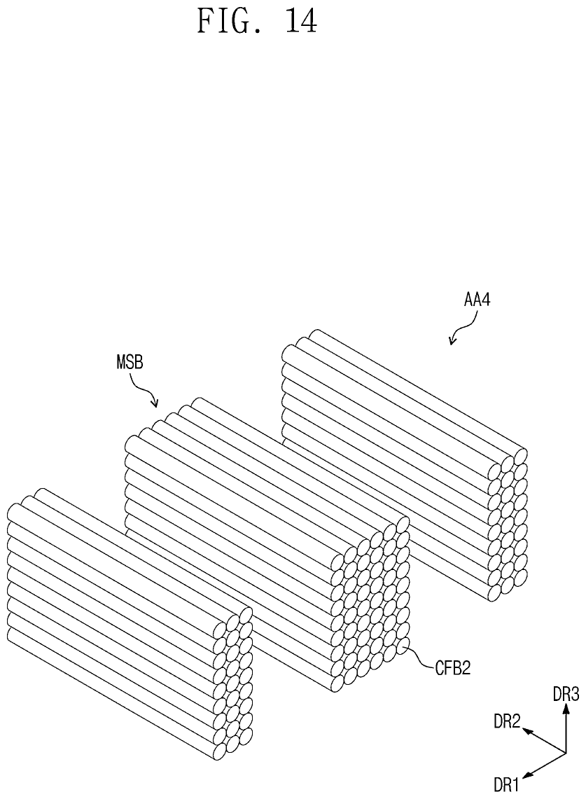

FIG. 10 is an enlarged perspective view of first area AA1 illustrated in FIG. 6. FIG. 11 is an enlarged plan view of second area AA2 illustrated in FIG. 10. FIG. 12 is a perspective view of third area AA3 illustrated in FIG. 10.

Referring to FIG. 10, the first support plate MTP1 may include the first fixed part LF1 and the first expanded part LE1. The first expanded part LE1 may extend from the first fixed part LF1 in the first direction DR1. The first fixed part LF1 and the first expanded part LE1 may be arranged in the first direction DR1. Hereinafter, the first fixed part LF1 may be defined as a first flat part PLA1, and the first expanded part LE1 may be defined as a flexible part EFP.

The first flat part PLA1 may have a flat plate shape defined by the first direction DR1 and the second direction DR2. The first flat part PLA1 may include the first plane PLT1, the first folding portion PLF1, and the second plane PLT2. The first plane PLT1, the first folding portion PLF1, and the second plane PLT2 may be arranged in the first direction DR1.

The first openings OP1 may be defined in the first folding portion PLF1. The first openings OP1 may be arranged in a predetermined rule. The first openings OP1 may be arranged in a grid shape, and a grid pattern may be formed in the first folding portion PLF1.

As the first openings OP1 are defined in the first folding portion PLF1, an area of the first folding portion PLF1 is reduced, and thus the rigidity of the first folding portion PLF1 may be lowered. Thus, when the first openings OP1 are defined in the first folding portion PLF1, the flexibility of the first folding portion PLF1 may increase as compared to a case in which the first openings OP1 are not defined in the first folding portion PLF1. As a result, the first folding portion PLF1 may be folded more easily.

Referring to FIGS. 10, 11, and 12, the flexible part EFP may include a plurality of first portions PT1 and a plurality of second portions PT2. The first portions PT1 may extend in the second direction DR2. The second portions PT2 may extend in the second direction DR2.

The first portions PT1 and the second portions PT2 may be alternately arranged in the first direction DR1. The second portions PT2 may be arranged between the first portions PT1 adjacent to each other. Flexible openings LOP, which will be described below, may be defined in the second portions PT2. The flexible openings LOP might not be defined in the first portions PT1.

The first support plate MTP1 may include a plurality of first carbon fibers CFB1. For example, FIG. 12 illustrates the first carbon fibers CFB1 of the flexible part EFP, but the present disclosure is not necessarily limited thereto, and the first flat part PLA1 may also include the first carbon fibers CFB1.

The first carbon fibers CFB1 may include carbon fiber reinforced plastics (CFRPs). For example, the first carbon fibers CFB1 may be prepreg. As the first support plate MTP1 includes the CFRP, a weight of the first support plate MTP1 may be smaller than a weight of a plate including stainless steel (SUS).

As illustrated in FIG. 12, the first carbon fibers CFB1 may be laminated in a plurality of layers in the third direction DR3. For example, in FIG. 12, the first carbon fibers CFB1 may be laminated in first to fourth layers LY1 to LY4 in order from the bottom to the top. However, this is an example, and the number of laminated first carbon fibers CFB1 is not necessarily limited thereto.

Among the layers in which the first carbon fibers CFB1 are laminated, an extension direction and an arrangement direction of the first carbon fibers CFB1 on at least one layer may be different from extension directions and arrangement directions of the first carbon fibers CFB1 on the other layers. For example, as illustrated in FIG. 12, the first carbon fibers CFB1 of the first layer LY1 may be arranged in the first direction DR1 and extend in the second direction DR2. The first carbon fibers CFB1 on the second layer LY2 and the third layer LY3 may extend in the first direction DR1 and be arranged in the second direction DR2. The first carbon fibers CFB1 disposed on the fourth layer LY4 may be arranged in the first direction DR1 and extend in the second direction DR2.

However, this is an example, and FIG. 12 illustrates that the extension directions of the first carbon fibers CFB1 arranged on different layers are perpendicular to each other, but the extension directions and the arrangement directions of the first carbon fibers CFB1 may change depending on folding or sliding characteristics of the display device DD (see FIG. 1).

Among the layers in which the first carbon fibers CFB1 are laminated, the first carbon fibers CFB1 arranged on at least one layer are arranged in different directions, and thus the rigidity and resilience of the flexible part EFP may increase. For example, the flexible part EFP including the first carbon fibers CFB1 arranged in different directions may have greater rigidity than that of the flexible part EFP including the first carbon fibers CFB1 arranged in the same direction. Accordingly, when the display device DD (see FIG. 1) is changed from the contraction mode to the expansion mode, the second portions PT2 of the flexible part EFP may maintain the rigidity and resilience. Thus, the folding or sliding reliability of the display device DD (see FIG. 1) may be increased.

The plurality of flexible openings LOP may be defined in the second portions PT2. The flexible openings LOP might not be defined in the first portions PT1. The flexible openings LOP may be defined by the first carbon fibers CFB1 arranged in the second portions PT2.

When viewed on a plane, the flexible openings LOP may be arranged in the first direction DR1 and the second direction DR2. The flexible openings LOP may extend longer in the second direction DR2 than in the first direction DR1. The flexible openings LOP arranged in an h^{th} column may be arranged alternately with the flexible openings LOP arranged in a (h+1)^{th} column. The column may correspond to the second direction DR2. Here, h is a positive integer.

The second portions PT2 may include first branch portions BR1 and second branch portions BR2. The first branch portions BR1 may be arranged between the flexible openings LOP adjacent to each other in the first direction DR1. The second branch portions BR2 may be arranged between the flexible openings LOP adjacent to each other in the second direction DR2. The first branch portions BR1 may extend in the second direction, and the second branch portions BR2 may extend in the first direction DR1. The flexible openings LOP may be defined by the first and second branch portions BR1 and BR2.

As the flexible openings LOP are defined, the rigidity of the flexible part EFP may be lowered. Thus, when the flexible openings LOP are defined in the first support plate MTP1, the flexibility of the first support plate MTP1 may increase as compared to a case in which the flexible openings LOP are not defined in the first support plate MTP1. As a result, the first support plate MTP1 may be more easily bent. As illustrated in FIGS. 3 and 4, a portion of the flexible part EFP may be more easily bent and accommodated inside the second case CS2.

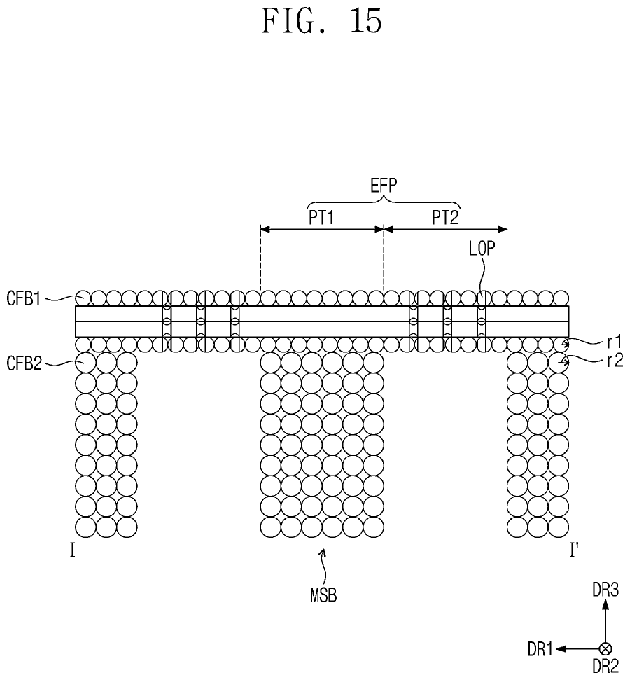

FIG. 13 is a perspective view of a second support plate illustrated in FIG. 4. FIG. 14 is a perspective view of fourth area AA4 illustrated in FIG. 13. FIG. 15 is a cross-sectional view for describing coupling between a flexible part of FIG. 12 and support bars of FIG. 13.

For example, FIG. 15 is a cross-sectional view along line I-I′ illustrated in FIG. 4.

For convenience of description, in FIG. 15, the display module DM illustrated in FIG. 4 is omitted.

Since the flexible part EFP illustrated in FIG. 15 is the same as the flexible part EFP illustrated in FIG. 12, a description thereof may be substantially similar to corresponding elements described above and to the extent that an element is not described in detail with respect to this figure, it may be understood that the element is at least similar to a corresponding element that has been described elsewhere within the present disclosure.

Referring to FIG. 13, the second support plate MTP2 may include the second fixed part LF2 and the second expanded part LE2. The second fixed part LF2 and the second expanded part LE2 may be arranged in the first direction DR1. When the second fixed part LF2 is unfolded, the second fixed part LF2 may have a flat plate shape defined by the first direction DR1 and the second direction DR2. Hereinafter, the second fixed part LF2 may be defined as a second flat part PLA2.

The second flat part PLA2 may include the third plane PLT3, the second folding portion PLF2, and the fourth plane PLT4. The third plane PLT3, the second folding portion PLF2, and the fourth plane PLT4 may be arranged in the first direction DR1.

As the second openings OP2 are defined in the second folding portion PLF2, an area of the second folding portion PLF2 is reduced, and thus the rigidity of the second folding portion PLF2 may be lowered. Thus, when the second openings OP2 are defined in the second folding portion PLF2, the flexibility of the second folding portion PLF2 may increase as compared to a case in which the second openings OP2 are not defined in the second folding portion PLF2. As a result, the second folding portion PLF2 may be folded more easily.

The second expanded part LE2 may include the plurality of support bars MSB. The support bars MSB and the second flat part PLA2 may be arranged in the first direction DR1. The support bars MSB may extend in the second direction DR2 and be arranged in the first direction DR1.

Referring to FIGS. 13 and 14, the support bars MSB may include a plurality of second carbon fibers CFB2. The second carbon fibers CFB2 may include the CFRPs. As the support bars MSB include the CFRPs, a weight of the second support plate MTP2 may be smaller than the weight of the plate including stainless steel (SUS).

As illustrated in FIG. 14, the second carbon fibers CFB2 may be laminated in a plurality of layers. For example, in FIG. 14, the second carbon fibers CFB2 are laminated in nine layers in the third direction DR3, but the number of laminated second carbon fibers CFB2 might not necessarily be limited thereto.

The second carbon fibers CFB2 disposed in each layer may be arranged in the first direction DR1. The second carbon fibers CFB2 disposed in each layer may extend in the second direction DR2. An extension direction and an arrangement direction of the second carbon fibers CFB2 adjacent to each other in the third direction DR3 may be the same. However, the present disclosure is not necessarily limited thereto, and the extension direction and the arrangement direction of the second carbon fibers CFB2 may change depending on the folding or sliding characteristics of the display device DD (see FIG. 1).

When the display device DD (see FIG. 3) is changed from the expansion mode to the contraction mode or from the contraction mode to the expansion mode, an external force may be applied to the support bars MSB in the first direction DR1. The second carbon fibers CFB2 may extend to be perpendicular to an application direction of the external force and may be arranged in the application direction of the external force. Accordingly, the rigidity of the support bars MSB may increase. Thus, even when an external force is applied to the support bars MSB, the support bars MSB might not be deformed, and thus the sliding reliability of the display device DD (see FIG. 3) may be increased.

Referring to FIGS. 14 and 15, the support bars MSB may adhere to the flexible part EFP. For example, the support bars MSB may adhere to lower surfaces of the first portions PT1. Each of the support bars MSB may adhere to a lower surface of the corresponding first portion PT1 among the first portions PT1. The support bars MSB may overlap the first portions PT1. The adhesion between the support bars MSB and the flexible part EFP will be described in detail in FIG. 18C.

When viewed from the second direction DR2, the first carbon fibers CFB1 may have a first radius r1. The second carbon fibers CFB2 may have a second radius r2. When viewed from the second direction DR2, a size of the first radius r1 of the first carbon fibers CFB1 and a size of the second radius r2 of the second carbon fibers CFB2 may be different from each other. The size of the first radius r1 may be smaller than the size of the second radius r2.

As the sizes of the radii of the carbon fibers CFB1 and CFB2 become larger, resistance to the external force may become greater. As the sizes of the radii of the carbon fibers CFB1 and CFB2 become larger, the rigidity may become greater. For example, the support bars MSB including the second carbon fibers CFB2 may have high rigidity, and the flexible part EFP including the first carbon fibers CFB1 may have a relatively smaller rigidity than that of the support bars MSB.

Accordingly, when the display device DD (see FIG. 3) is changed to the expansion mode or the contraction mode, even when the external force is applied to the support bars MSB, the support bars MSB might not be deformed. Further, due to the small rigidity, the flexible part EFP may be more easily folded and accommodated in the case CS (see FIG. 3) in the contraction mode and may be more easily restored to a flat shape in the expansion mode. Thus, the sliding reliability of the display device DD (see FIG. 3) may be increased.

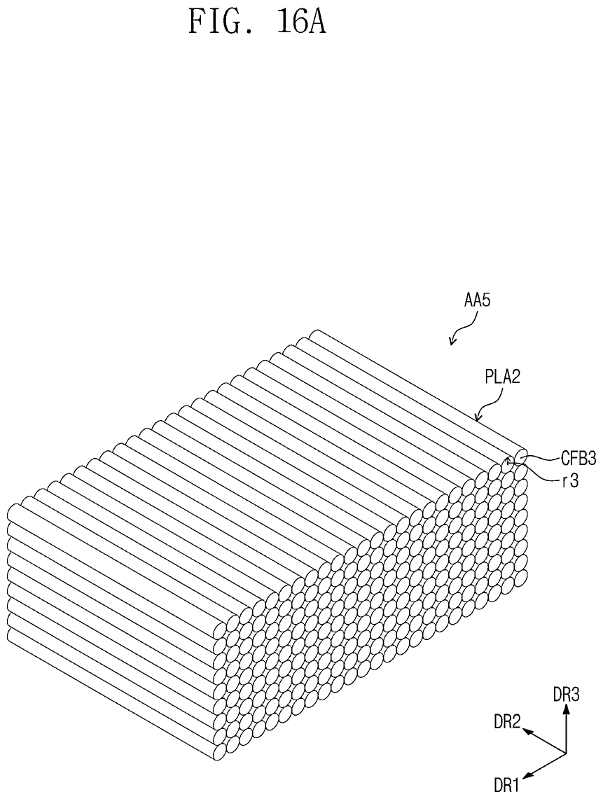

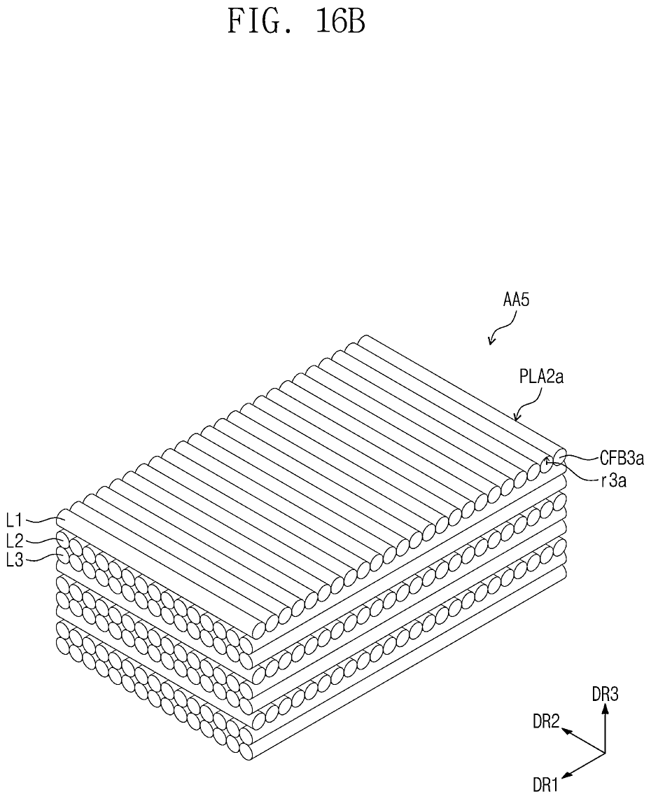

FIG. 16A is a perspective view illustrating a second flat part illustrated in FIG. 13. FIG. 16B is a view for describing the second flat part according to an embodiment.

For example, FIGS. 16A and 16B are perspective views of a fifth area AA5 illustrated in FIG. 13.

Referring to FIGS. 15 and 16A, the second flat part PLA2 may include a plurality of third carbon fibers CFB3. The third carbon fibers CFB3 may include the CFRPs. For example, the third carbon fibers CFB3 may be prepreg. As the second flat part PLA2 includes the CFRP, a weight of the second flat part PLA2 may be smaller than the weight of the plate including stainless steel (SUS).

The second flat part PLA2 may be laminated in a plurality of layers in the third direction DR3. For example, in FIG. 16A, nine layers are laminated, but the number of laminated layers of the third carbon fibers CFB3 is not necessarily limited thereto.

The third carbon fibers CFB3 laminated in each layer may be arranged in the first direction DR1 and extend in the second direction DR2. When viewed from the second direction DR2, the third carbon fibers CFB3 may have a third radius r3. The size of the third radius r3 may be the same as the size of the second radius r2 in FIG. 15. In this case, since the second carbon fibers CFB2 and the third carbon fibers CFB3 are substantially the same, the second flat part PLA2 and the support bars MSB may be manufactured simultaneously from a preliminary second support plate PMTP2 (see FIG. 18B). However, this is an example, and the present disclosure is not necessarily limited thereto.

Referring to FIGS. 15 and 16B, a second flat part PLA2a of FIG. 16B may include a plurality of third carbon fibers CFB3a. The third carbon fibers CFB3a may be laminated in the third direction DR3.

Among the layers in which the third carbon fibers CFB3a are laminated, an extension direction and an arrangement direction of the third carbon fibers CFB3a arranged on at least one layer may be different from extension directions and arrangement directions of the third carbon fibers CFB3a on the other layers. For example, in a direction from an upper side to a lower side, the third carbon fibers CFB3a on a first layer L1 may be arranged in the first direction DR1 and may extend in the second direction DR2. A second layer L2 may be disposed in the second direction DR2 and may extend in the first direction DR1. A third layer L3 may be disposed in the second direction DR2 and may extend in the first direction DR1. However, this is an example, and the extension direction and the arrangement direction of the third carbon fibers CFB3a on each layer may change depending on the folding and sliding characteristics of the display device DD (see FIG. 1).

When viewed from the second direction DR2, the third carbon fibers CFB3a may have a third radius r3a. The size of the third radius r3a and the size of the second radius r2 may be different from each other. The size of the third radius r3a may be smaller than the size of the second radius r2.

In this case, since the second carbon fibers CFB2 and the third carbon fibers CFB3a include the CFRPs having different sizes, the support bars MSB and the second flat part PLA2a may be formed through different processes and then connected to each other.

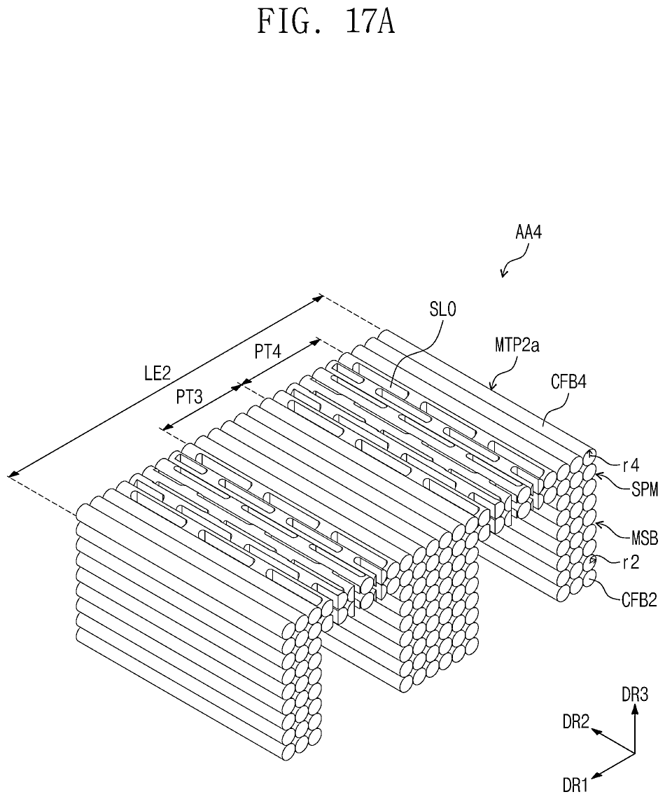

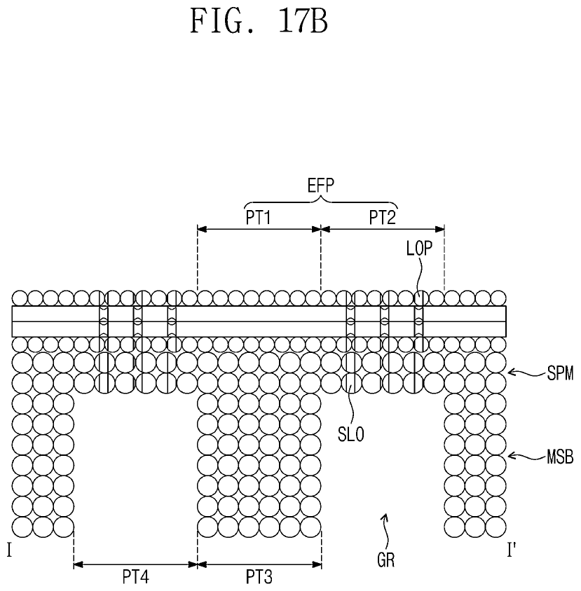

FIGS. 17A and 17B are views for describing a second support plate according to an embodiment.

For example, FIG. 17A is a perspective view of a fourth area AA4 illustrated in FIG. 13, and FIG. 17B is a cross-sectional view along line I-I′ illustrated in FIG. 4.

For example, only the second expanded part LE2 of the second support plate MTP2 is illustrated.

For convenience of description, in FIG. 17B, the display module DM illustrated in FIG. 4 is omitted.

Since the flexible part EFP in FIG. 17B is the same as the flexible part EFP in FIG. 12, a description thereof may be substantially similar to corresponding elements described above and to the extent that an element is not described in detail with respect to this figure, it may be understood that the element is at least similar to a corresponding element that has been described elsewhere within the present disclosure.

Referring to FIG. 17A, a second support plate MTP2a may further include a sub-plate SPM. The sub-plate SPM may be disposed on upper surfaces of the support bars MSB. The support bars MSB may be arranged on a lower surface of the sub-plate SPM.

The sub-plate SPM may be parallel to the plane defined by the first direction DR1 and the second direction DR2. The sub-plate SPM may include a plurality of fourth carbon fibers CFB4. The fourth carbon fibers CFB4 may include the CFRPs. As the sub-plate SPM includes the CFRPs, a weight of the sub-plate SPM may be smaller than the weight of the plate including stainless steel (SUS).

The fourth carbon fibers CFB4 may be laminated in a plurality of layers. For example, in FIG. 17A, the fourth carbon fibers CFB4 may be laminated in two layers. However, the present disclosure is not necessarily limited thereto, and the number of laminated fourth carbon fibers CFB4 may change depending on the folding or sliding characteristics of the display device DD (see FIG. 1).

The fourth carbon fibers CFB4 of the sub-plate SPM disposed on each layer may extend in the second direction DR2 and may be arranged in the first direction DR1. However, this is an example, and an extension direction and an arrangement direction of the fourth carbon fibers CFB4 may change.

When viewed from the second direction DR2, the fourth carbon fibers CFB4 may have a fourth radius r4. The size of the fourth radius r4 may be the same as the size of the second radius r2.

A plurality of sub-openings SLO may be defined in the sub-plate SPM. The sub-openings SLO may pass through the sub-plate SPM. Hereinafter, portions of the sub-plate SPM in which the sub-openings SLO are not defined are defined as third portions PT3, and portions of the sub-plate SPM in which the sub-openings SLO are defined are defined as fourth portions PT4.

As the sub-openings SLO are defined, the rigidity of the sub-plate SPM may be lowered. Thus, when the sub-openings SLO are defined in the sub-plate SPM, the flexibility of the sub-plate SPM may increase as compared to a case in which the sub-openings SLO are not defined in the sub-plate SPM. As a result, the sub-plate SPM may be bent more easily.

The support bars MSB may overlap the third portions PT3. The support bars MSB may be arranged on lower surfaces of the third portions PT3 of the sub-plate SPM. The support bars MSB might not overlap the fourth portions PT4. The support bars MSB might not overlap the sub-openings SLO.

Referring to FIGS. 17A and 17B, the sub-plate SPM may adhere onto a lower surface of the flexible part EFP. The third portions PT3 of the sub-plate SPM may adhere to the lower surfaces of the first portions PT1 of the flexible part EFP. The fourth portions PT4 of the sub-plate SPM may adhere to lower surfaces of the second portions PT2 of the flexible part EFP. The support bars MSB may overlap the first portions PT1 and the third portions PT3.

As the sub-plate SPM adheres to the lower surface of the flexible part EFP, the support bars MSB may be more easily connected to the flexible part EFP.

The flexible openings LOP and the sub-openings SLO may overlap each other. The flexible openings LOP and the sub-openings SLO may be connected to each other in the third direction DR3. As the sub-openings SLO are defined, when the display device DD (see FIG. 3) slides, the rigidity of the sub-plate SPM is lowered, and thus may be more easily bent. Accordingly, when the display device DD (see FIG. 3) is in the contraction mode, the second support plate MTP2 (see FIG. 13) may be more easily accommodated in the case CS (see FIG. 4). Further, when the display device DD (see FIG. 3) is in the expansion mode, the second support plate MTP2 may be exposed from the case CS (see FIG. 4) and may be more easily maintained in a flat state.

FIGS. 18A to 18E are perspective views illustrating a method of manufacturing the flexible part and the support bars illustrated in FIG. 15.

For example, FIGS. 18A to 18E are perspective views.

For convenience of description, FIGS. 18A to 18E illustrate only portions of the flexible part EFP and the support bars MSB.

Referring to FIG. 18A, a method of manufacturing the flexible part EFP (see FIG. 12) may include an operation of manufacturing a preliminary first support plate PMTP1. The preliminary first support plate PMTP1 may be manufactured by laminating the plurality of first carbon fibers CFB1. For example, the first carbon fibers CFB1 may be laminated in first to fourth layers LY1, LY2, LY3, and LY4.

For example, the first carbon fibers CFB1 arranged on the first layer LY1 may extend in the second direction DR2 and may be arranged in the first direction DR1. The first carbon fibers CFB1 arranged on the second layer LY2 may extend in the first direction DR1 and may be arranged in the second direction DR2. The first carbon fibers CFB1 arranged on the third layer LY3 may extend in the first direction DR1 and may be arranged in the second direction DR2. The first carbon fibers CFB1 arranged on the fourth layer LY4 may extend in the second direction DR2 and may be arranged in the first direction DR1. However, this is an example, and the extension directions and the arrangement directions of the first carbon fibers CFB1 may change depending on the folding or sliding characteristics of the display device DD (see FIG. 1).

Referring to FIG. 18B, a method of manufacturing the support bars MSB (see FIG. 14) may include an operation of manufacturing the preliminary second support plate PMTP2. The preliminary second support plate PMTP2 may be manufactured by laminating the plurality of second carbon fibers CFB2. For example, the second carbon fibers CFB2 may extend in the second direction DR2 and may be arranged in the first direction DR1 and the third direction DR3. However, this is an example, and the extension direction and the arrangement direction of the second carbon fibers CFB2 may change.

Referring to FIG. 18C, after the preliminary first support plate PMTP1 and the preliminary second support plate PMTP2 are manufactured, an operation of adhering the preliminary first support plate PMTP1 and the preliminary second support plate PMTP2 to each other may then be performed.

For example, the preliminary first support plate PMTP1 may be disposed on an upper surface of the preliminary second support plate PMTP2. When the preliminary first support plate PMTP1 is disposed on the upper surface of the preliminary second support plate PMTP2, pressure may be applied to the preliminary first support plate PMTP1 and the preliminary second support plate PMTP2. However, the present disclosure is not necessarily limited thereto, and heat may be applied to the preliminary first support plate PMTP1 and the preliminary second support plate PMTP2 to adhere the preliminary first support plate PMTP1 and the preliminary second support plate PMTP2.

Referring to FIG. 18D, after the preliminary first support plate PMTP1 and the preliminary second support plate PMTP2 adhere to each other, an operation of manufacturing the support bars MSB of the second support plate MTP2 may be performed. The operation of manufacturing the support bars MSB may include an operation of etching the preliminary second support plate PMTP2. The plurality of support bars MSB may be manufactured by dry etching or wet etching the preliminary second support plate PMTP2. However, the present disclosure is not necessarily limited thereto, and the plurality of support bars MSB may be manufactured by removing a portion of the second preliminary support plate PMTP2 using a laser beam.

Referring to FIG. 18E, an operation of defining the flexible openings LOP in the first support plate MTP1 may be performed. After the support bars MSB are manufactured, the flexible openings LOP may be defined in the preliminary first support plate PMTP1. The flexible openings LOP may be formed by irradiating the preliminary first support plate PMTP1 with a laser beam. However, this is an example, and the flexible openings LOP may be defined through other processes.

After the flexible part EFP and the support bars MSB are separately manufactured, a process for joining the flexible part EFP and the support bars MSB may be performed. The process of joining the flexible part EFP and the support bars MSB may be performed through a resin or a laser beam.

When the flexible part EFP and the support bars MSB are joined to each other through the resin, a height of the resin applied between the flexible part EFP and the support bars MSB might not be uniform. Accordingly, a distance between the flexible part EFP and the support bars MSB might not be constant. Thus, the surface quality of the display device DD (see FIG. 1) may be lowered.

When the flexible part EFP and the support bars MSB are joined to each other through the laser beam, the support bars MSB may be arranged on the lower surfaces of the first portions PT1 of the flexible part EFP, and the flexible part EFP may be irradiated with the laser beam. In this case, when positions of the flexible part EFP and the support bars MSB are changed due to errors in a process, defective joining between the flexible part EFP and the support bars MSB may occur.

Further, the first support plate MTP1 and the second support plate MTP2 are manufactured in different processes and jointed to each other, and thus a process time may increase.

According to the method of manufacturing a display device, according to an embodiment of the present disclosure, the flexible part EFP and the support bars MSB may be formed integrally, for example, they may together be part of a singular uninterrupted structure. Accordingly, the process of joining the flexible part EFP and the support bars MSB may be omitted. Thus, the process time may be saved.

Further, since the flexible part EFP and the support bars MSB are not joined through the resin, a gap between the flexible part EFP and the support bars MSB may be maintained constant, and the surface quality of the display device DD (see FIG. 1) may be increased.

As well, since the flexible part EFP and the support bars MSB are not joined through the laser beam, even when an error occurs in the positions of the flexible part EFP and the support bars MSB, occurrence of the defective joining between the flexible part EFP and the support bars MSB may be prevented.

When the flexible part EFP and the support bars MSB are manufactured, the flexible part EFP and the support bars MSB may be arranged on the lower surface of the display module DM of FIG. 4.

According to an embodiment of the present disclosure, first carbon fibers of a first support plate disposed under a display panel may be laminated in a plurality of layers. Among the plurality of layers, an arrangement direction of the first carbon fibers on at least one layer may be different from an arrangement direction of the first carbon fibers on the other layers. Accordingly, when the display device is folded or slid, the first support plate may maintain rigidity and a restoring force. Thus, the folding or sliding reliability of the display device may be increased.

Support bars of a second support plate disposed below the first support plate may include second carbon fibers. The second carbon fibers may extend and be laminated in a second direction. Accordingly, when the display device is slid in the second direction, the support bars may maintain rigidity. Thus, the sliding reliability of the display device may be increased.

According to an embodiment of the present disclosure, the flexible part and the support bars may be manufactured after a preliminary first support plate and a preliminary second support plate adhere to each other. Accordingly, as compared to a case in which the flexible part and the support bars are manufactured through separate processes and joined to each other, a process time may be reduced, and a possibility of occurrence of defects in the display device in a process of joining the flexible part and the support bars may be reduced.

Although an embodiment of the present disclosure has been described above, those skilled in the art may understand that the present disclosure may be variously modified and changed without departing from the spirit and scope of the present disclosure. Further, it should be interpreted that an embodiment disclosed in the present disclosure is not necessarily intended to limit the technical spirit of the present disclosure.

What is claimed is:

1. A display device, comprising:
a display panel including a fixed area and an expanded area extending from the fixed area in a first direction;
a first support plate including:
a first flat part disposed under the fixed area, and
a flexible part disposed under the expanded area; and
a second support plate including a plurality of support bars arranged under the flexible part, arranged in the first direction, and extending in a second direction intersecting the first direction,
wherein the flexible part includes a first carbon fiber,
wherein each of the plurality of support bars includes a second carbon fiber, and
wherein a size of a radius of the first carbon fiber and a size of a radius of the second carbon fiber are different from each other.

2. The display device of claim 1, wherein the radius of the second carbon fiber is larger than the radius of the first carbon fiber.

3. The display device of claim 1, wherein the first carbon fiber includes a plurality of first carbon fiber structures, and the plurality of first carbon fiber structures are laminated in a plurality of layers.

4. The display device of claim 3, wherein among the layers in which the plurality of first carbon fiber structures are laminated, an extension direction of each of the plurality of first carbon fiber structures on at least one layer and an extension direction of each of the plurality of first carbon fiber structures on at least other one layer are different from each other.

5. The display device of claim 1, wherein the second carbon fiber includes a plurality of second carbon fiber structures, and the plurality of second carbon fiber structures are laminated in a plurality of layers.

6. The display device of claim 5, wherein in each of the plurality of layers, the plurality of second carbon fiber structures are arranged in the first direction and extend in the second direction.

7. The display device of claim 1, wherein the flexible part includes:
a plurality of first portions overlapping the support bars; and
a plurality of second portions which are arranged between neighboring pairs of the plurality of first portions and in which a plurality of flexible openings are defined.

8. The display device of claim 1, wherein the fixed area includes a first non-folding area, a folding area, and a second non-folding area that are arranged in the first direction.

9. The display device of claim 8, wherein the first flat part includes:
a first plane overlapping the first non-folding area;
a first folding portion which overlaps the folding area and in which a plurality of first openings are defined; and
a second plane overlapping the second non-folding area.

10. The display device of claim 9, wherein the second support plate further includes:
a second flat part including a third carbon fiber and disposed under the first flat part.

11. The display device of claim 10, wherein the third carbon fiber includes a plurality of third carbon fiber structures, and the plurality of third carbon fiber structures are laminated in a plurality of layers.

12. The display device of claim 11, wherein the plurality of third carbon fiber structures laminated on each layer are arranged in the first direction and extend in the second direction.

13. The display device of claim 11, wherein, among the layers in which the plurality of third carbon fiber structures are laminated, an extension direction of the each of the plurality of third carbon fiber structures on at least one layer and an extension direction of each of the plurality of the third carbon fiber structures on the other layers are different from each other.

14. The display device of claim 10, wherein the second flat part includes:
a third plane overlapping the first plane;
a second folding portion which overlaps the first folding portion and in which a plurality of second openings are defined; and
a fourth plane overlapping the second plane.

15. The display device of claim 1, wherein the second support plate further includes:
a sub-plate disposed on a lower surface of the flexible part, and the support bars are arranged on a lower surface of the sub-plate.

16. The display device of claim 15, wherein the sub-plate includes a plurality of fourth carbon fiber structures arranged in the first direction and extending in the second direction, and
wherein the size of the radius of each of the plurality of second carbon fiber structures is the same as a size of a radius of each of the plurality of the fourth carbon fibers.

17. A method of manufacturing a display device, the method comprising:
forming a preliminary first support plate by laminating a plurality of first carbon fibers;
forming a preliminary second support plate by laminating a plurality of second carbon fibers;
adhering the preliminary first support plate to an upper surface of the preliminary second support plate;
forming a plurality of support bars by etching the preliminary second support plate;
forming a flexible part by defining a plurality of flexible openings in the preliminary first support plate; and
connecting the flexible part and the support bars to a display panel,
wherein a size of a radius of each of the first carbon fibers is smaller than a size of a radius of each of the second carbon fibers.

18. The method of claim 17, wherein the first carbon fibers are laminated in a plurality of layers, and among the layers in which the first carbon fibers are laminated, an extension direction of each of the first carbon fibers on at least one layer and an extension direction of each of the first carbon fibers on at least another layer are different from each other.

19. The method of claim 18, wherein the second carbon fibers are laminated in a plurality of layers, and in each of the plurality of layers, each of the second carbon fibers are arranged in a first direction and extend a second direction intersecting the first direction.

20. The method of claim 17, wherein in the forming of the support bars, the support bars are formed by dry etching or laser etching the preliminary second support plate.
